(19) United States
(12) Patent Application Publication
(10) Pub. No.: US 2019/0090375 A1
(43) Pub. Date: Mar. 21, 2019

(54) INSERTING KEYED MODULES IN CHASSIS

(71) Applicant: HEWLETT PACKARD ENTERPRISE DEVELOPMENT LP, Houston, TX (US)

(72) Inventors: Eugene Yan Ki Hsue, Fremont, CA (US); Harold Zin Htutt, Fremont, CA (US); Robert Eugene Cayou, Fremont, CA (US); Vance Murakami, Fremont, CA (US)

(21) Appl. No.: 15/708,774

(22) Filed: Sep. 19, 2017

(51) Int. Cl. H05K 7/14

(52) U.S. Cl. CPC H05K 7/1489; H05K 7/1401

(57) ABSTRACT

Examples herein relate to a keying device for inserting a module in a chassis. The device comprises a key plate having a protrusion adapted to interlock with a slot of the chassis and teeth to grip the module and an operating handle. The keying device permits insertion or ejection of the module in the chassis responsive to the protrusion interlocking the slot of the chassis when the operating handle is in an open position and the keying device rejects insertion or ejection of the module in the chassis responsive to the protrusion not interlocking the slot of the chassis when the operating handle is in a closed position.

### BACKGROUND

Storage systems consist of a chassis and modules received in the chassis. The main chassis is considered the infrastructure of the storage system and the modules are related to power supplies, controllers, host bus adapters (HBA's), etc. that are mounted within the infrastructure of the storage system, creating a final storage product. These modules may require a particular design with specific physical dimensions and specific electrical consumption requirements in order to be physically integrated into the infrastructure of the storage system.

### BRIEF DESCRIPTION OF THE DRAWINGS

The following detailed description references the drawings, wherein:

FIG. 1 illustrates an example of a keying device according to the present disclosure.

FIG. 2 illustrates a storage system and an example of a keying device according to the present disclosure.

FIG. 3 illustrates another example of a keying device according to the present disclosure.

FIG. 4 illustrates a storage system and an example of a keying device according to the present disclosure.

FIG. 5 illustrates another example of a keying device according to the present disclosure.

FIG. 6 illustrates a storage system and an example of a keying device according to the present disclosure.

FIG. 7A and FIG. 7B illustrate a flowchart of an example of a method for inserting a module into a storage system.

FIG. 8A and FIG. 8B illustrate a flowchart of an example of another method for inserting a module into a storage system.

### DETAILED DESCRIPTION

The present disclosure relates to devices that improve the integration of modules (e.g. a controller node into an infrastructure of a storage system). The controller node can house central processor units (CPUs), dual in-line memory modules (DIMMs), application-specific integrated circuits (ASICs) etc.

With the increase of storage product physical configurations, standardizing the chassis designs (i.e. standardizing the physical dimensions of the chassis) across a products portfolio can be convenient for the time to market, industrial design, and product cost. Various chassis and module designs are created that adhere to industry standardized physical dimensions, but may include vendor and application specific differences that can cause physical damage to the module and/or the chassis when an inappropriate module is inserted into a chassis designed to accept modules with similar, but ultimately incompatible physical characteristics. The chassis and modules can look similar so keying them to prevent physical damage may be desired.

In this respect, in order to ensure that different modules (e.g. controller nodes or memory nodes) of the storage product cannot interchange with an incorrect main chassis of the infrastructure of the storage system and cause physical damage, a stacked keying design prevents inappropriate modules from being inserted into a main chassis. The stacked keying design can be integrated into the module chassis insertion/ejector mechanisms and can comprise one or more plates having at least one protrusion that can interlock with a slot of the chassis insertion/ejector mechanism at a predetermined height and thus, avoiding the manufacturing of additional chassis mechanisms.

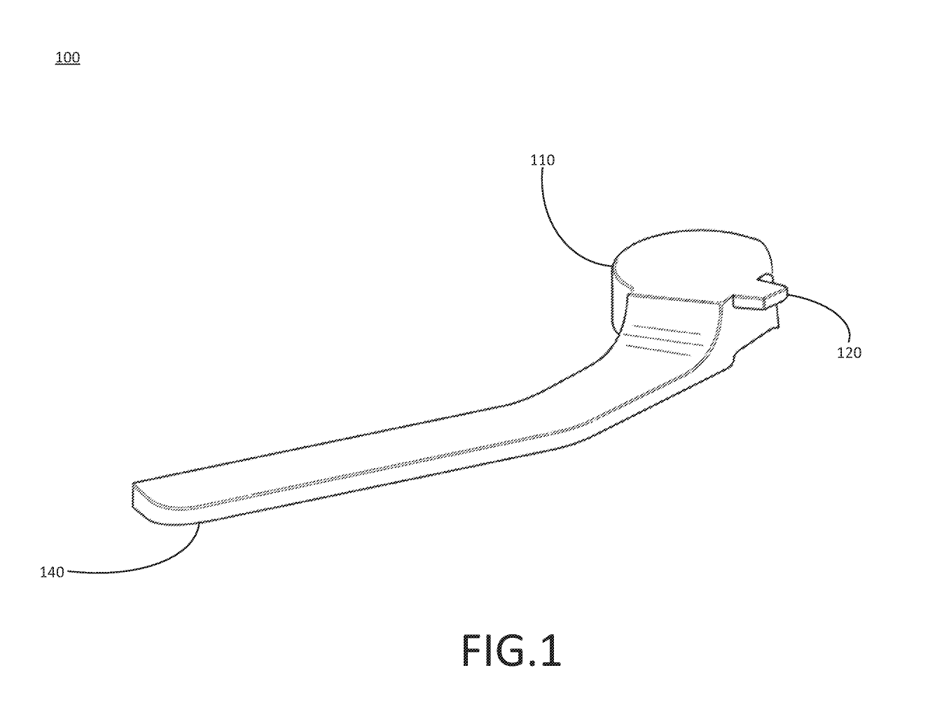

FIG. 1 shows an example of a keying device 100 for insertion and/or ejection of a module in a storage system as e.g. a server/rack server comprising a module chassis according to the present disclosure. The device 100 comprises a key plate 110 having a protrusion 120 to interlock with a slot of the module chassis (not shown). Furthermore, the key 140 comprises an operating handle 140 connected to the key plate 110. The operating handle 140 may permit operating the keying device 100 to reject or permit insertion of the module into the storage system and to reject or permit ejection of the module from the storage system.

By operating the handle 140, the keying device 100 permits insertion of the module into the storage system comprising a module chassis if the protrusion 120 of the device 100 interlocks the slot of the module chassis. On the other hand, the keying device 100 rejects insertion of the module into the storage system if the protrusion 120 does not interlock the slot of the chassis.

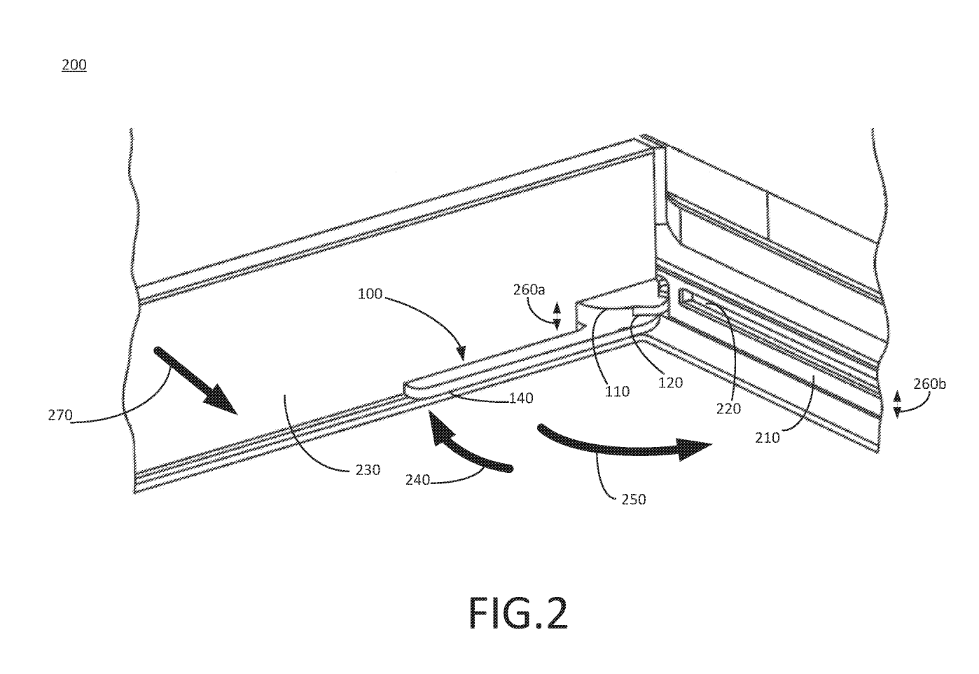

By operating the handle 140, the keying device 100 permits ejection of the module inserted in the storage system if the protrusion 120 of the device 100 interlocks the slot of the module chassis. On the other hand, the keying device 100 rejects ejection of the module from the storage system if to the protrusion 120 does not interlock the slot of the chassis. FIG. 2 shows how to perform insertion and ejection of the module with the keying device 100.

FIG. 2 shows an example storage system 200 having a module chassis insertion/ejector mechanism 210. The storage system 200 can receive modules that comprise a keying device that may be compatible with the module chassis insertion/ejector mechanism 210. Modules comprising a keying device not compatible with the module chassis insertion/ejector mechanism 210 cannot be inserted into the module chassis so physical damage to the chassis or to those modules can be prevented.

In particular, FIG. 2 shows an example storage system 200 having a module 230 inserted. The storage system 200 comprises the module chassis insertion/ejector mechanism 210. The module 230 can be selected from a storage module, a processing module, a combination thereof, or any other appropriate server module as e.g. composer, memory module, fabric module, etc. FIG. 2 shows the keying device 100 integrated in the module 230 to permit or reject ejection of the module 230 from the storage system 200. The keying device 100 can be integrated in the module 230 on a side of the module 230. In another example, two to four keying devices can be integrated in the module 230.

As it is shown in the figure, the key plate 110 of the keying device 100 has a protrusion 120 that can interlock with a slot 220 of the module chassis insertion/ejector mechanism 210. The handle 140 of the keying device can be in an open position by moving the handle 140 in a direction shown by arrow 250 or in a closed position by moving the handle 140 in a direction shown by arrow 240.

Ejection of the Module 230 from the Storage System 200 (Shown in FIG. 2):

In the closed position of the handle 140 (i.e. the handle 140 facing the front of the module 230) as it is shown in FIG. 2, the keying device rejects ejection of the module 230 from the storage system 200 when the protrusion 120 does not interlock the slot 220 of the module chassis 210. The ejection of the module 230 is performed in the direction shown by arrow 270. In order to permit the protrusion 120 to interlock with the slot 220 of the module chassis 210 the handle 140 must be in an open position and there must be an alignment in height between the protrusion 120 and the slot 220 of the module chassis 210. In particular, the protrusion 120 may be established at a predetermined height shown by arrow 260a which should be equal to the predetermined height of the slot 220 established on the module chassis mechanism 210 and shown by arrow 260b to correctly interlock the protrusion 120 with the stot 220. Hence, as the operating handle 140 is in the closed position (and not in the open position) the protrusion 120 does not interlock the slot 220 of the chassis 210 and therefore, the keying device 100 rejects the ejection of the module 230 from the storage system 200.

In an open position of the handle 140 (not shown in FIG. 2) that would be caused if the handle 240 is moved in the direction shown by arrow 250 (i.e. the handle 140 facing the module chassis 210), the keying device 100 may permit ejection of the module 230 from the storage system 200 when the protrusion 120 interlocks s the slot 220 of the module chassis 210 after the operating handle 140 being moved toward the chassis 210. Hence, with the operating handle 140 being in the open position, the protrusion 120 could interlock the slot 220 of the module chassis 210 and therefore, the keying device would permit the ejection of the module 230 from the storage system 200

As it is shown in FIG. 2 the protrusion 120 has a predetermined height shown by arrow 260a which is (and should be) equal to the height of the slot 220 established on the module chassis insertion/ejector mechanism 210 and shown by arrow 260b. When the height of the protrusion 120 of the key plate 110 and the height of the slot 220 of the module chassis 210 is the same, the protrusion 120 can interlock the slot 220 of the module chassis 210 when the handle 140 is moved in the direction shown by arrow 250 as previously described and hence, permitting ejection of the module from the storage system In contrast to this, if there is a misalignment between the protrusion 120 and the slot 220 of the module chassis 210, (e.g. the protrusion is too high or too low compared to the slot 200 established on the module chassis 210) this would cause the protrusion 120 not to interlock with the slot 220 of the module chassis 210 when the handle 140 is moved in the direction shown by arrow 250 and hence, the ejection of the module from the storage system would not be permitted.

### Insertion of the Module Into the Storage System 200 (Not Shown in FIG. 2):

In a closed position of the handle 140 (i.e. the handle 140 facing the front of the module 230), the module 230 could not be inserted into the storage system 200 because the protrusion 120 would not interlock the slot 220 of the module chassis 210 and therefore, the keying device would reject the insertion of the module 230 into the storage system 200.

In the open position of the handle 140 (i.e. the handle 240 facing the module chassis 210), the module 230 could be inserted into the storage system 200 because the protrusion 120 would correctly interlock the slot 220 of the module chassis 210 and therefore, the keying device would permit the insertion of the module 230 into the storage system 200.

In order to permit the protrusion 120 to interlock with the slot 220 of the module chassis 210 to insert the module 230 into the storage system 200, the handle 140 must be in the open position and there must be an alignment in height between the protrusion 120 and the slot 220 of the module chassis 210. In particular, the protrusion 120 may be established at a predetermined height shown by arrow 260a which should be equal to the predetermined height of the slot 220 established on the module chassis mechanism 210 and shown by arrow 260b.

As it is shown in FIG. 2 the protrusion 120 has a predetermined height shown by arrow 260a which is (and should be) equal to the height of the slot 220 established on the module chassis insertion/ejector mechanism 210 and shown by arrow 260b. When the height of the protrusion 120 of the key plate 110 and the height of the slot 220 of the module chassis 210 is the same, the protrusion 120 can interlock the slot 220 of the module chassis 210 if the handle 140 is in the open position (i.e. the handle 140 facing the slot 220 of the module chassis 210), permitting insertion of the module into the storage system. In contrast to this, if the handle 140 is in the open position but there is a misalignment between the protrusion 120 and the slot 220 of the module chassis 210 (i.e. the protrusion is too high or too low compared to the slot 200 established on the module chassis 210) the protrusion 120 would not interlock with the slot 220 of the module chassis 210 and hence, the insertion of the module into the storage system would not be permitted.

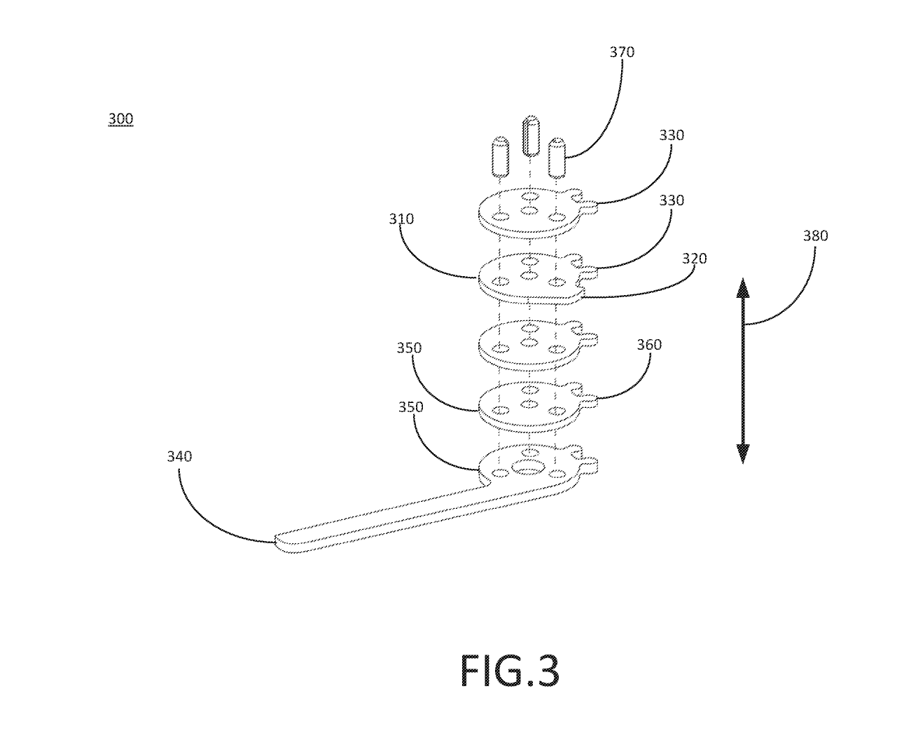

FIG. 3 shows another example of a keying device 300 for permitting or rejecting insertion/ejection of a module in a module chassis insertion/ejector mechanism of a storage system. The keying device 300 comprises a key plate 310 having a protrusion 320 to interlock with a slot of the module chassis insertion/ejector mechanism of a storage system (not shown) and several teeth 330 to grip the module chassis and an operating handle 340 connected to a pinion plate 350. The device 300 further comprises two additional pinion plates 350 to stack (elevate) the key plate 310 to a predetermined height as shown by arrow 380 with respect to the handle 340. The device further comprises an additional pinion plate 350. The pinion plates 350 also comprise teeth 330 to grip the module chassis. As previously mentioned, when the height of the protrusion 320 of the key plate 310 and the height of the slot of the module chassis is the same, the protrusion can interlock the slot of the module chassis and hence, ejection or insertion of the module from and into the storage system may be permitted.

In this respect, the keying device 300 (as well as keying device 100) can be integrated in a module as shown in previous FIG. 2. The key plate 310 of the device 300 can be restacked by adding or subtracting pinion plates 350 so the module computing device could match a predetermined module chassis to be inserted into a storage system (e.g. by interlocking the protrusion 320 with the slot of the module chassis). The keying devices require no modification of the module chassis and avoid the manufacturing or tooling up of a new chassis so they are cost effective. Actually, the module chassis can be adjusted once it is set up in a data center. Furthermore, the module configuration design enables the keying devices to be modified on a factory floor before they are released.

As previously mentioned, stacking the key plate 310 to a predetermined height (as shown by arrow 380) may permit the protrusion 320 to interlock with a slot of the module chassis when operating the handle is in an open position as mentioned in FIG. 2. In other examples, different amounts of pinion plates 350 could be used in other examples of the device 300 to stack the key plate 310 to different heights to interlock the protrusion with slots established at different heights.

Furthermore, the device 300 comprises a plurality of mechanical attachment components to connect the key plate 310, the three pinion plates 350 and the operating handle 340. In particular, the device 300 comprises three spring pins 370 to connect the aforementioned elements.

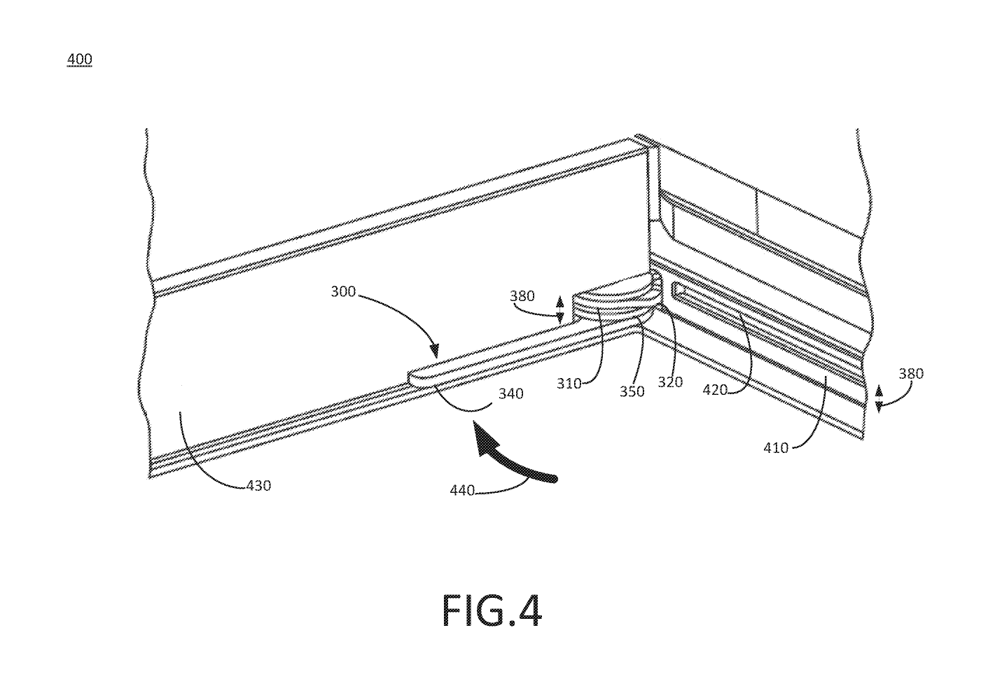

FIG. 4 shows an example storage system 400 having a module chassis insertion/ejector mechanism 410. The storage system 400 receives modules (e.g. module 430). FIG. 4 shows the storage system 400 with the module 430 received in the chassis 410 of the system 400. The module 430 can be one of: a storage module, a processing module, a fabric module, or a combination thereof. FIG. 4 also shows the keying device 300 for inserting or ejecting the module 430 in the chassis 410 previously shown in FIG. 3.

As it is shown in the figure, the key plate 310 has a protrusion 320 that can interlock with a slot 420 of the chassis 410. In the closed position, the keying device rejects insertion or ejection of the module in the chassis responsive to the protrusion 320 not interlocking the slot 420 of the chassis 410. The key device 300 is in the open position in FIG. 4. The key plate 310 is stacked with the pinion plates 350 at the predetermined height as shown by arrow 380 as it was indicated in previous FIG. 3. This may permit the protrusion 320 to interlock with the slot 420 of the chassis 410 (when the operating handle is in the open position) as the slot 420 is also established at the same predetermined height shown by arrow 380.

The operating handle 340 moves in the direction shown by arrow 440 toward the module 230 after the insertion of the module 430 into the chassis 410 of the storage system 400. Hence, the operating handle 140 is in the closed position and the protrusion 120 cannot interlock the slot 220 of the chassis 210 and therefore, the module 230 cannot be ejected from the chassis 210.

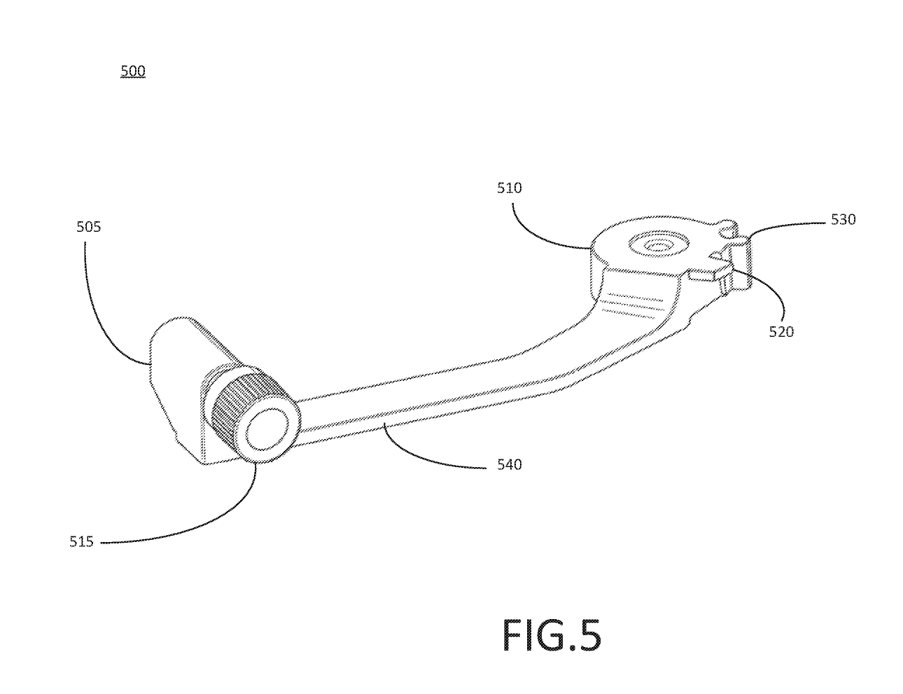

FIG. 5 shows another example of a keying device 500 according to the present disclosure. The keying device 500 comprises a handle 540, a key plate 510 connected to the handle 540. The key plate 510 comprises a protrusion 520 and teeth 530 to grip a module chassis. Furthermore, the keying device 500 comprises a thumbscrew 515 having a receiver 505 to fix the keying device 500 to a module after to avoid e.g. moving the handle 540 from a close position to an open position.

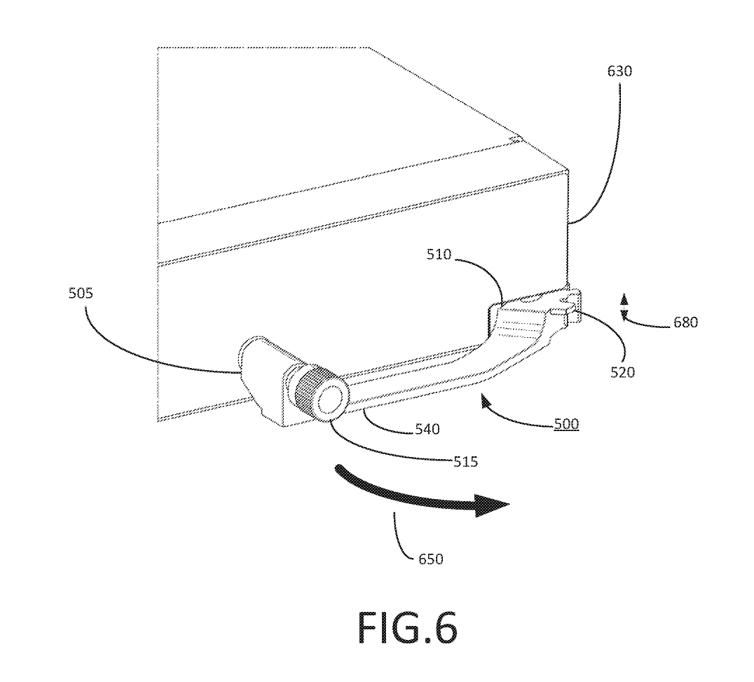

FIG. 6 shows a module 630 and the keying device 500 previously shown in FIG. 5. The keying device 500 comprises the handle 540 and the key plate 510 and the thumbscrew 520 having the receiver 505 that permits the device 500 to be fixed against the module 630.

As it is shown in FIG. 6 the protrusion 520 has a predetermined height shown by arrow 680 which should be equal to the height of a slot established on a module chassis insertion/ejector mechanism (not shown). When the height of the protrusion 520 of the key plate 510 and the height of the slot of the module chassis matches, the protrusion 520 can interlock the slot of the module chassis when the handle 540 is moved in the direction shown by arrow 650 only if the thumbscrew 515 is unscrewed from the receiver 505 to permit movement of the handle 540. If the thumbscrew 515 is not unscrewed from the receiver 505, the handle 540 cannot be moved in the direction shown by arrow 650 to its open position and the module 630 cannot be ejected from the storage system.

Furthermore, if there is a misalignment between the protrusion and the slot of the module chassis this would cause the protrusion 120 not to interlock with the slot 220 of the module chassis 210 even though the thumbscrew 515 is unscrewed from the receiver 505 and hence, the ejection of the module from the storage system would not be permitted.

Hence, in order to permit the protrusion 520 to interlock with the slot of the module chassis to insert or eject the module 630 into/from the storage system, the thumbscrew 515 must be unscrewed from the receiver 505, the handle 540 must be moved in the direction shown by arrow 650 to its open position and there must be an alignment in height between the protrusion 520 and the slot of the module chassis. In particular, the protrusion 520 and the slot may be established at a predetermined height shown by arrow 680.

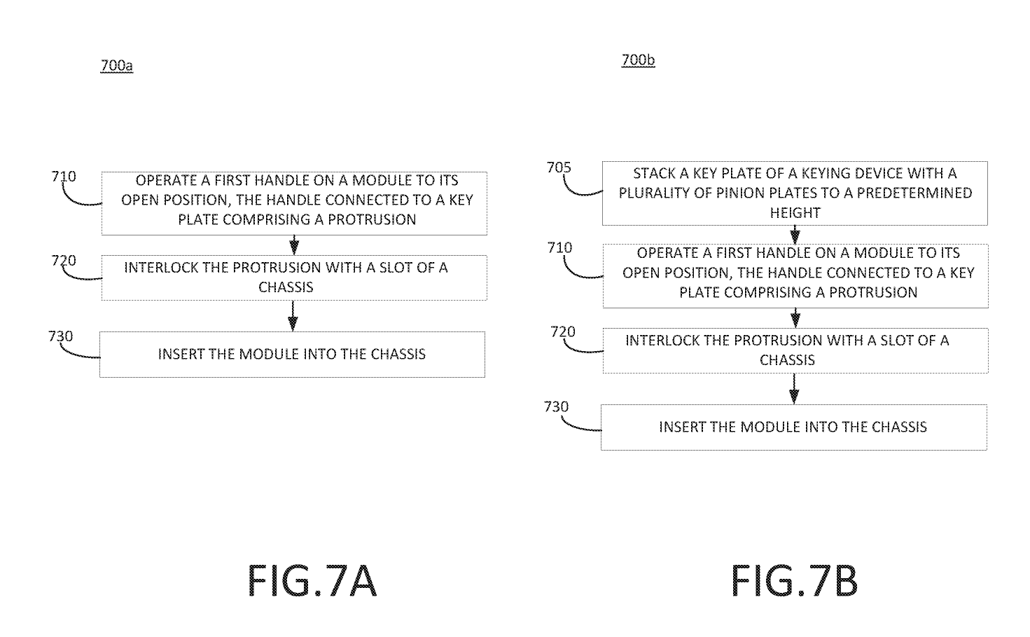

FIG. 7A shows a flowchart of an example of a method 700a for inserting a module into a storage system by using a keying device as shown in FIG. 1. The method 700a comprises a step 710 for operating a first handle on a module to its open position. The handle is connected to a key plate. The key plate having a protrusion adapted to interlock with a slot of a module chassis. The method 700a also comprises a step 720 for interlocking the protrusion with the slot of the module chassis and a step 730 for inserting the module into the module chassis.

In some implementations, the method 700a comprises a step for operating the handle to a closed position (as shown in previous FIG. 2) to reject ejection of the module from the module chassis responsive to the protrusion not interlocking the slot of the chassis. Furthermore, the method 700a comprises a step for operating the handle back to an open position to permit ejection of the module from the chassis responsive to the protrusion interlocking the slot of the chassis.

FIG. 7B shows flowchart of an example of a method 700b for inserting a module into a storage system by using a keying device as shown in FIG. 3. The method 700b comprises a step 705 for stacking the key plate with a plurality of pinion plates at a predetermined height as shown in previous FIG. 3. Similar to method 700a, the method 700b comprises a step 710 for operating a first handle on a module to its open position. The handle is connected to a key plate. The key plate having a protrusion adapted to interlock with a slot of a module chassis. The method 700b also comprises a step 720 for interlocking the protrusion with the slot of the module chassis and a step 730 for inserting the module into the module chassis.

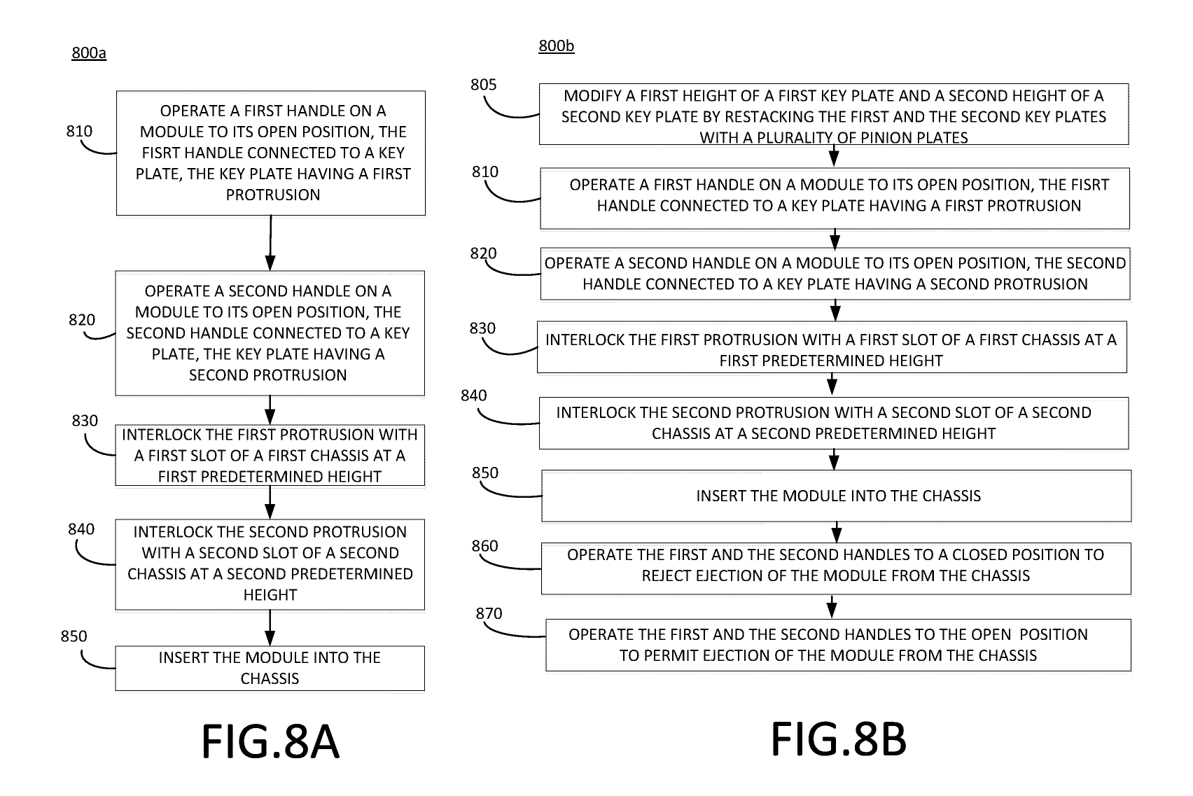

FIG. 8A illustrates a flowchart of an example of another method 800a for inserting a module into a storage system.

The method 800a comprises a step 810 for operating a first handle on a module to its open position, the first handle connected to a first key plate and a plurality of pinion plates to stack the first key plate to a first predetermined height, the first key plate having a first protrusion adapted to interlock with a first slot of a module chassis at the first predetermined height.

The method 800a comprises a step 820 for operating a second handle on the module to its open position, the second handle connected to a second key plate and a plurality of pinion plates to stack the second key plate to a second predetermined height, the second key plate having a second protrusion adapted to interlock with a slot of a second module chassis at the second predetermined height. In some examples, the first predetermined height and the second predetermined height are the same. Most likely, in practice, the slot would be the same height on both sides of a module.

The method 800a comprises a step 830 for interlocking the first protrusion with the first slot of the first module chassis at the first predetermined height and a step 840 for interlocking the second protrusion with the second slot of the second module chassis at the second predetermined height. Furthermore, the method 800a comprises a step 850 for inserting the module into the chassis.

FIG. 8B illustrates a flowchart of an example of another method 800b for inserting a module into a storage system. The method 800b comprises a step 805 for modifying a first predetermined height of a first key plate by restacking the first key plate with a plurality of pinion plates and modifying a second predetermined height of a second key plate by restacking the second key plate with a plurality of pinion plates.

Similar to method 800a, the method 800b comprises a step 810 for operating a first handle on a module to its open position, the first handle connected to the first key plate and the plurality of pinion plates, the first key plate having a first protrusion adapted to interlock with a first slot of a module chassis at the first predetermined height.

The method 800b comprises a step 820 for operating a second handle on the module to its open position, the second handle connected to the second key plate and a plurality of pinion plates, the second key plate having a second protrusion adapted to interlock with a slot of a second module chassis at the second predetermined height.

The method 800b comprises a step 830 for interlocking the first protrusion with the first slot of the first module chassis at the first predetermined height and a step 840 for interlocking the second protrusion with the second slot of the second module chassis at the second predetermined height. Furthermore, the method 800b comprises a step 850 for inserting the module into the chassis.

In some implementations, the method 800b comprises a further step 860 for operating the first and the second handles to a closed position to reject ejection of the module from the chassis responsive to the first and the second protrusions not interlocking the first and the second slots, respectively, and a step 870 for operating the first and the second handles back to the open position to permit ejection of the module from the first and second module chassis responsive to the first and the second protrusions interlocking the first and the second slots, respectively.

Relative terms used to describe the structural features of the figures illustrated herein are in no way limiting to conceivable implementations. It is, of course, not possible to describe every conceivable combination of components or methods, but one of ordinary skill in the art will recognize that many further combinations and permutations are possible. Accordingly, the present disclosure is intended to embrace all such alterations, modifications, and variations that fall within the scope of this application, including the appended claims. Additionally, where the disclosure or claims recite “a,” “an,” “a first,” or “another” element, or the equivalent thereof, it should be interpreted to include one or more than one such element, neither requiring nor excluding two or more such elements.

1. A keying device for inserting a module in a chassis, the device comprising:
a key plate having a protrusion to interlock with an slot of the chassis; and
an operating handle,
wherein the keying device permits insertion or ejection of the module in the chassis responsive to the protrusion interlocking the slot of the chassis when the operating handle is in an open position; and
wherein the keying device rejects insertion or ejection of the module in the chassis responsive to the protrusion not interlocking the slot of the chassis when the operating handle is in a closed position.

2. The keying device of claim 1, further comprising at least one pinion plate to stack the key plate at a predetermined height and teeth to the grip the chassis.

3. The keying device of claim 2, further comprising a plurality of mechanical attachment components to connect the key plate, the pinion plate and the operating handle.

4. The keying device of claim 3, wherein the mechanical attachment components are spring pins.

5. The keying device of claim 2, wherein the plurality of pinion plates comprise three pinion plates.

6. The keying device of claim 1, wherein:
the chassis is the infrastructure of a storage system; and
the module is a controller node or a memory node.

7. The keying device of claim 1, further comprising a thumbscrew to fix the keying device to the module.

8. A method, the method comprising:
operating a first handle on a module to its open position, wherein the handle is connected to a key plate, the key plate having a protrusion adapted to interlock with a slot of a chassis;
interlocking the protrusion with the slot of the chassis; and
inserting the module into the chassis.

9. The method of claim 8, further comprising:
operating the handle to a closed position to reject ejection of the module from the chassis responsive to the protrusion not interlocking the slot of the chassis.

10. The method of claim 8, further comprising:
operating the handle back to an open position to permit ejection of the module from the chassis responsive to the protrusion interlocking the slot of the chassis.

11. The method of claim 8, further comprising:
stacking the key plate with a plurality of pinion plates at a predetermined height.

12. A method, the method comprising:
operating a first handle on a module to its open position, the first handle connected to a first key plate and at least one pinion plates to stack the first key plate at a first predetermined height, the first key plate having a first protrusion adapted to interlock with a first slot of the chassis at the first predetermined height;
operating a second handle on the module to its open position, the second handle connected to a second key plate and at least one pinion plate to stack the second key plate at a second predetermined height, the second key plate having a second protrusion adapted to interlock with a second slot of the chassis at the second predetermined height;
interlocking the first protrusion with the first slot of the chassis at the first predetermined height;
interlocking the second protrusion with the second slot of the chassis at the second predetermined height; and
inserting the module into the chassis.

13. The method of claim 12, further comprising:
operating the first and the second handles to a closed position to reject ejection of the module in the chassis responsive to the first and the second protrusions not interlocking the first and the second slots, respectively.

14. The method of claim 13, further comprising:
operating the first and the second handles back to the open position to permit ejection of the module in the chassis responsive to the first and the second protrusions interlocking the first and the second slots, respectively.

15. The method of claim 12, further comprising:
modifying the first predetermined height of the first key plate by restacking the first key plate and the plurality of pinion plates; and
modifying the second predetermined height of the second key plate by restacking the second key plate and the plurality of pinion plates.
